(19) United States
(12) Patent Application Publication
(10) Pub. No.: US 2004/0169190 A1
(43) Pub. Date: Sep. 2, 2004

(54) Semiconductor pressure sensor device

(76) Inventors: Masato Ueno, Anjo-city (JP); Yoshifumi Watanabe, Kariya-city (JP)

Correspondence Address: POSZ & BETHARDS, PLC, 11250 ROGER BACON DRIVE, SUITE 10, RESTON, VA, 20190, US

(21) Appl. No.: 10/779,658

(22) Filed: Feb. 18, 2004

(30) Foreign Application Priority Data
Feb. 27, 2003 (JP) 2003-50933

(51) Int. Cl. H01L 33/00

(52) U.S. Cl. 257/99

(57) ABSTRACT

A semiconductor pressure sensor device has a fully-filling gel structure including a sensor chip for detecting a pressure and generating an electrical signal corresponding to the pressure. This sensor chip of the sensor device is connected with a conductive member such as a terminal using a bonding wire. The sensor chip and bonding wire are covered by a protective member that has characteristics of electric insulation and plasticity. Here, the bonding wire is formed of an alloy of Au and Pd. This structure using a bonding wire of an Au-Pd alloy enables wire strength to be enhanced without the wire diameter being largely increased in comparison with a conventional one.

### CROSS REFERENCE TO RELATED APPLICATIONS

This application is based on and incorporates herein by reference Japanese Patent Application No. 2003-50933 filed on Feb. 27, 2003.

### FIELD OF THE INVENTION

The present invention relates to a semiconductor pressure sensor device having a sensor chip and a bonding wire, both of which are covered by a protective member such as a gel. The semiconductor pressure sensor device is suitably used for detecting an engine intake pressure of a vehicle.

### BACKGROUND OF THE INVENTION

For instance, JP-A-2001-153746 (U.S. Pat. No. 6,512,255) discloses a semiconductor pressure sensor device having a semiconductor sensor chip for detecting a pressure and generating an electrical signal corresponding to the pressure. This sensor chip of the sensor device is connected with a conductive member such as a terminal using a bonding wire formed of Au (gold) or Al (aluminum). The sensor chip and bonding wire are covered by a protective member that has electrical insulation and plasticity.

For instance, the sensor device is applied to a sensor for detecting a pressure within an intake manifold of a vehicle engine, namely MAPS (Manifold Absolute Pressure Sensor) that is used for a primary sensor controlling an intake manifold pressure.

In the above-mentioned semiconductor pressure sensor device, a sensor chip and a bonding wire are covered by a protective member formed of a gel such as a silicon gel and fluorine gel, so that they are called “fully-filling gel structure.” By contrast, “partially-filling gel structure” indicates a structure where the sensor chip is covered but the bonding wire is not covered by the protective member.

The fully-filling gel structure is superior to the partially-filling gel structure with respect to a characteristic for protecting a sensor chip or a bonding wire. For instance, the manifold absolute pressure sensor recently tends to adopt the fully-filling gel structure as a result of consideration of sludge resistance, freezing resistance, or influence of contamination due to an EGR (Exhaust Gas Recirculation) gas.

Further, in the semiconductor pressure sensor device having the fully-filling gel structure, a circuit chip is provided as needed for processing an electrical signal from a sensor chip. Here, the circuit chip and the sensor chip are electrically connected by a bonding wire, and the circuit chip and bonding wire are also covered by a protective member.

Further, in the semiconductor pressure sensor device having the fully-filling gel structure, the bonding wires between the sensor chip and conductive member and between the sensor chip and circuit chip are formed of Au (gold) or Al (aluminum).

In particular, a bonding pad on the chip is generally formed of a base material using Al, so that gold is mainly applied to a bonding wire owing to its superiority to Al with respect to connecting strength.

However, in the semiconductor pressure sensor device having the fully-filling gel structure, the protective member formed of the gel or the like is constricted and swollen owing to a cooling/heating cycle. This generates a stress applied to a bonding wire, resulting in decrease of a product life-cycle of the device, for instance, owing to breakage of a neck portion of the bonding wire.

Further, when a diameter of a wire is increased for enhancing the life-cycle of the bonding wire, a bonding pad of the chip needs to be enlarged. This is not preferable for a chip structure that requires larger scale integration. For instance, a diameter of a bonding wire is conventionally 30 to 40 μm, so that a diameter being larger than 40 μm is not preferable.

Further, when a diameter of a bonding wire is increased, an additional stress is generated pertinent to increase in wire strength, reducing a life-cycle of the wire and increasing costs.

Further, when strength of the wire becomes too strong, the wire tends to not follow variations of the protective member formed of a gel or the like, potentially harming the protective member and generating a bubble within the protective member during the cooling/heating cycle. By contrast, this may exhibit a breakage of the wire owing to not following the variations of the protective member.

### SUMMARY OF THE INVENTION

It is an object of the present invention to provide a semiconductor pressure sensor device, having a fully-filling gel structure, capable of enhancing strength of a bonding wire without largely increasing a diameter of the bonding wire.

To achieve the above object, a semiconductor pressure sensor device is provided with the following. A sensor chip is provided for detecting a pressure and generating an electrical signal corresponding to the pressure. The sensor chip is electrically connected with a conductive member using a bonding wire. The sensor chip and bonding wire are covered by a protective member. Here, the bonding wire is formed of an alloy of Au and Pd. This structure using a bonding wire of an Au-Pd alloy enables wire strength to be enhanced without the wire diameter being largely increased in comparison with a conventional one.

In another aspect of the present invention, the bonding wire preferably has a diameter of not larger than 40 μm. This structure using a bonding wire having a diameter of not larger than 40 μm enables wire strength to be enhanced with a diameter near a diameter of a conventional bonding wire.

### BRIEF DESCRIPTION OF THE DRAWINGS

The above and other objects, features, and advantages of the present invention will become more apparent from the following detailed description made with reference to the accompanying drawings. In the drawings:

FIG. 1 is a cross-sectional view showing a main part of a semiconductor sensor pressure device according to an embodiment of the present invention; and

FIG. 2 is a perspective view showing a main part of a semiconductor sensor pressure device according to another embodiment of the present invention.

### DETAILED DESCRIPTION OF THE PREFERRED EMBODIMENTS

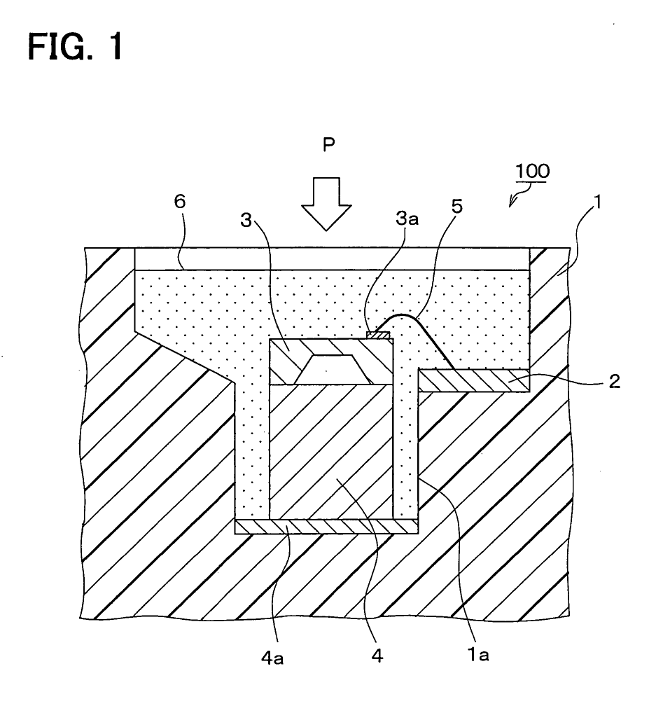

A semiconductor pressure sensor device 100 according to an embodiment of the present invention will be explained with reference to FIG. 1 showing its main structure. For instance, the sensor device 100 is used for detecting an intake pressure of a vehicle engine.

As shown in FIG. 1, a casing 1 is formed of resin such as epoxy resin containing fillers, PPS (polyphenylene sulfide), or PBT (polybutylene telephthalate).

In the casing 1, a terminal (conductive member) 2 formed of conductive material such as copper is integrally disposed by insert molding. The terminal 2 outwardly exposes at a given portion of the casing 1 for being electrically connected with an external wiring member.

Further, in the casing 1, a semiconductor sensor chip 3 is disposed for detecting a pressure and generating an electrical signal corresponding to the detected pressure. The sensor chip 3 has a well-known structure to utilize a piezo-resistance effect. Since a diaphragm and diffusion resistance formed on the diaphragm are provided in the sensor chip 3, the electrical signal is generated according to a stress (pressure) applied on the sensor chip 3 in a thickness direction.

The sensor chip 3 is die-bonded onto the bottom surface of a recess portion 1a via a glass base 4 with an adhesive 4a such as a phlorosilicone origin adhesive.

On the upper surface of the sensor chip 3, a bonding pad 3a is disposed. The bonding pad 3a is typically an aluminum film of an aluminum base material formed through evaporation or sputtering. Here, the bonding pad 3a is an aluminum film of Al-Si-Cu (Si: silicon, Cu: copper) alloy although the aluminum base material can be Al, Al-Si, Al-Si-Cu, or the like.

The terminal 2 and the bonding pad 3a of the sensor chip 3 are electrically connected by a bonding wire 5 formed of Au-Pd (gold-palladium) alloy, using a wedge bonding method.

The alloy composition of the bonding wire 5 can be Pd: 1 to 10%, Au: balance. The bonding wire 5 can have a diameter of not larger than 40 μm, preferably 30 to 40 μm. In the bonding wire 5 of this embodiment, the alloy composition is Au: 99% and Pd: 1%, while the diameter is 38 μm.

Within the casing 1, a protective member 6 made of an insulation material is filled as embedding the sensor chip 3 and bonding wire 5. The protective member 6 is for protecting the sensor chip 3 and the bonding wire 5, securing an insulating property and preventing corrosion of those members.

In detail, the protective member 6 covers and protects the sensor chip 3, bonding wire 5, the connection portions between the sensor chip 3 and the bonding wire 5, and the connection portions between the conductive member (lead member) 2 and the bonding wire 5.

The protective member 6 can use a gel material such as a fluorine gel, silicon gel, and phlorosilicone gel, each of which has a preferable characteristic such as electric insulation, plasticity, thermal shock resistance, vibration resistance, heat resistance, or low-temperature resistance. In this embodiment, a fluorine gel is used owing to the lowest moisture permeability among the gels used in the pressure sensor devices.

The protective member 6 formed of this fluorine gel is fed in a fluid state within the casing 1 provided with the sensor chip 3 and bonding wire 5, then undergoing a thermosetting treatment (for instance, at about 150° C. for 90 minutes) to be disposed.

In the above-mentioned semiconductor pressure sensor device 100, a stress (pressure) as a hollow arrow P shown in FIG. 1 is applied on the surface of the protective member 6, thereby reaching the sensor chip 3 via the protective member 6.

Here, the sensor chip 3 generates, according to the applied stress, an electrical signal that is outwardly outputted via the metal film 3a, bonding wire 5, and lead member 2, thereby enabling detection of the applied stress (pressure).

Next, a basis for adopting a bonding wire 5 of Au-Pd alloy will be explained. A cause of decreasing strength of a bonding wire is estimated that mutual diffusion of gold and aluminum is developed between a bonding wire of gold and a bonding pad of aluminum base material.

The inventors of the present invention estimate that aluminum tends to diffuse since the bonding wire is formed of pure gold, developing an idea that replacing the pure gold with other gold alloys disables the aluminum to easily diffuse. This idea leads to enhancement of strength of the bonding wire.

After examining various gold alloys, it is found that a gold alloy including palladium (Pd) can be preferably used for a bonding wire to achieve the object.

Detailed examination will be described below. At first, tensile strength was measured with respect to two specimens (first: a bonding wire of this embodiment, second: a conventional one of a reference). Here, in both the specimens, a bonding pad 3a disposed on the sensor chip 3 is formed of a 1.35 μm thick aluminum film of Al-Si-Cu. By contrast, regarding the bonding wire, the first includes a bonding wire 5 of this embodiment, namely a wire of Au-Pd (Pd: 1%, Au: balance), while the second includes a conventional reference wire of pure gold. Both the wires of the first and second specimens have the same diameter (e.g., 38 μm).

Posterior to 2 hour exposure at 175° C., a tension strength test was performed. In this test, a tensile strength is measured when a bonding wire is broken at a neck portion of a bonding wire. As a result, the tensile strength of the first specimen of this embodiment is 15 gf, while that of the second reference specimen is 9 gf, exhibiting enhancement of the strength in the bonding wire 5 of this embodiment.

Further, when a bonding pad 3a is formed of a 5.5 μm thick aluminum film of Al-Si, a superiority of the bonding wire 5 of this embodiment is also verified. Thus, adopting a bonding wire of Au-Pd alloy enhances the wire strength in comparison with the conventional wire.

Next, a cooling/heating cycle test was applied to three devices that have structures of the above-mentioned semiconductor pressure sensor 100. The first is a device 100 of this embodiment having a wire bonding of Au-Pd (Pd: 1%, Au: balance), while the second and third are reference devices having a conventional wire of pure gold. The wire of the first device has a diameter of 38 μm. By contrast, the wire of the second device (reference) has a conventional diameter of 30 μm, while that of the third device (reference) has a diameter of 50 μm, which is larger than that of a conventional one and improper for large scale integration.

To these devices, a cooling/heating cycle (−40° C. for 30 minutes, 125° C. for 30 minutes) that is a typical test condition for a vehicle was performed. As a result, the second device (reference) having a pure gold wire of +30 μm failed in a neck portion of the wire after hundreds of cycles. By contrast, the first device 100 of this embodiment and third device (reference) having a pure gold wire of φ50 μm failed after thousands of cycles that is increased by a factor of about 10 from that of the second device.

Thus, using an Au-Pd alloy bonding wire 5 of this embodiment can enhance wire strength with a wire diameter (e.g., φ40 μm) near a conventional diameter, i.e., without the wire diameter being largely increased and without restricting larger scale integration.

(Other Embodiment)

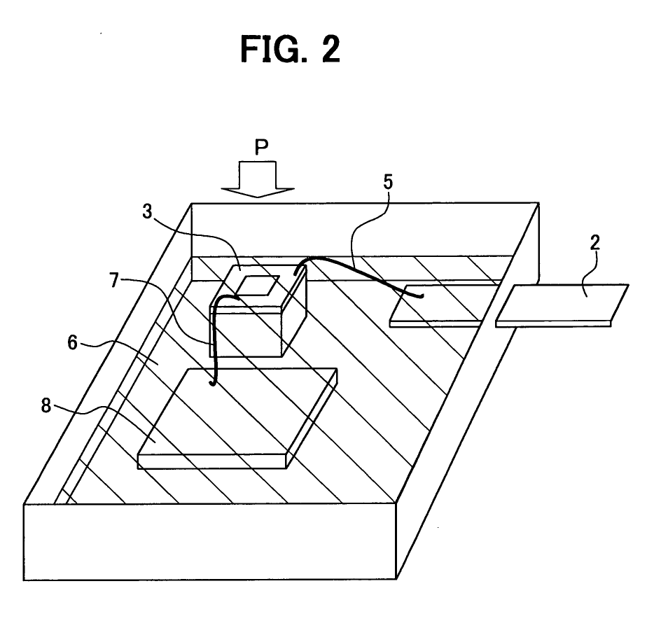

Furthermore, in the above semiconductor pressure sensor device 100, a circuit chip 8 can be additionally disposed for processing the electrical signal from the sensor chip 3, as shown in FIG. 2. Here, an additional bonding wire 7 electrically connects the circuit chip 8 and the sensor chip 3. In addition, a protective member 6 can cover the circuit chip 8 and the additional bonding wire 7.

In this structure, the additional bonding wire 7 can be formed of Au-Pd alloy. This also enables the additional bonding wire 7 for connecting chips 3, 8 to be strengthened in comparison with a conventional one without largely increasing a wire diameter.

It will be obvious to those skilled in the art that various changes may be made in the above-described embodiments of the present invention. However, the scope of the present invention should be determined by the following claims.

What is claimed is:

1. A semiconductor pressure sensor device comprising:
a conductive member;
a sensor chip for detecting a pressure and generating an electrical signal corresponding to the pressure;
a bonding wire electrically connecting the sensor chip and the conductive member; and
a protective member having characteristics of electric insulation and plasticity and covering the sensor chip and the bonding wire,
wherein the bonding wire is formed of an alloy of Au and Pd.

2. The pressure sensor device of claim 1,
wherein a diameter of the bonding wire is not larger than 40 μm.

3. The pressure sensor device of claim 1, further comprising:
a circuit chip for processing the electrical signal from the sensor chip; and
an additional bonding wire electrically connecting the circuit chip and the sensor chip,
wherein the protective member covers the circuit sensor chip and the bonding wire, and
wherein the additional bonding wire is formed of an alloy of Au and Pd.

4. The pressure sensor device of claim 3,
wherein a diameter of the additional bonding wire is not larger than 40 μm.
